(19) United States
(12) Patent Application Publication
(10) Pub. No.: US 2026/0026070 A1
(43) Pub. Date: Jan. 22, 2026

(54) SOURCE/DRAIN CONTACT IN SINGLE DIFFUSION BREAK REGION

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Julien Frougier, Albany, NY (US)

(21) Appl. No.: 18/779,323

(22) Filed: Jul. 22, 2024

(51) Int. Cl. H01L 29/417; H01L 21/283; H01L 23/528; H01L 27/088; H01L 29/06; H01L 29/40; H01L 29/423; H01L 29/66; H01L 29/775; H01L 29/786

(52) U.S. Cl. CPC H10D 64/258; H01L 21/283; H10D 64/01; H10D 84/83; H01L 23/528; H10D 30/014; H10D 30/43; H10D 30/6735; H10D 30/6757; H10D 62/121

(57) ABSTRACT

Embodiments of present invention provide a semiconductor structure. The semiconductor structure includes a first and a second transistor separated by a single diffusion break; and a source/drain contact to a source/drain region of the first transistor, the source/drain region being next to the single diffusion break, where the source/drain contact has an L-shape having a vertical portion on top of a horizontal portion, the horizontal portion extending at least partially into a sidewall spacer at a sidewall of the single diffusion break. A method of forming the same is also provided.

### BACKGROUND

The present application relates to manufacturing of semiconductor integrated circuits. More particularly, it relates to a method of forming source/drain contact in a single diffusion break region and the structure formed thereby.

As semiconductor industry moves towards smaller node, field-effect-transistors (FETs) are aggressively scaled to fit into reduced footprint or real estate with increased device density. For example, two sets of FETs, such as two sets of nanosheet transistors, may be vertically stacked together to double the density of FETs in a given footprint.

Transistors are powered through contacts made to the gate and source/drain regions of the transistors. However, when a gate contact is made to a gate of the transistor, at a location vertically above the active channel region such as vertically above the nanosheets of the transistor, the close proximity between the gate contact and a source/drain contact made to a source/drain region of the transistor makes it difficult, if not impossible, for the gate contact and the source/drain contact to connect a metal line on a same metal track.

### SUMMARY

Embodiments of present invention provide a semiconductor structure. The semiconductor structure includes a first and a second transistor separated by a single diffusion break; and a source/drain contact to a source/drain region of the first transistor, the source/drain region being next to the single diffusion break, where the source/drain contact has an L-shape having a vertical portion on top of a horizontal portion, the horizontal portion extending at least partially into a sidewall spacer at a sidewall of the single diffusion break.

In one embodiment, the horizontal portion of the source/drain contact extends into the single diffusion break and the vertical portion of the source/drain contact is partially embedded in the single diffusion break.

According to one embodiment, the semiconductor structure further includes a gate contact to a gate of the first transistor, the gate contact being directly above an active channel region of the first transistor.

According to another embodiment, the semiconductor structure further includes a metal track having a first portion and a second portion separated by a dielectric layer, a first via, and a second via; wherein the first via connects the source/drain contact to the first portion of the metal track and the second via connects the gate contact to the second portion of the metal track.

In one embodiment, a gap between the first and the second portion of the metal track is equal to or larger than two-third (⅔) of a length of the source/drain region of the first transistor.

According to yet another embodiment, the semiconductor structure further includes a third transistor underneath the first and the second transistor and the single diffusion break (SDB), the third transistor having a source/drain region next to a backside single diffusion break (BSDB) and a gate directly underneath the SDB, and a source/drain contact to the source/drain region of the third transistor that extends into the BSDB.

According to one embodiment, the semiconductor structure further includes a backside metal track, wherein the source/drain contact to the source/drain region of the third transistor connects to a first portion of the backside metal track, and a gate contact to the gate underneath the SDB connects to a second portion of the backside metal track.

In one embodiment, the source/drain contact to the source/drain region of the third transistor has an inverted L-shape with a vertical portion at least partially underneath the BSDB.

Embodiments of present invention further provide a method of forming a semiconductor structure. The method includes forming a first and a second transistor separated by a single diffusion break; forming an L-shaped source/drain contact of the first transistor, the L-shaped source/drain contact having a vertical portion on top of a horizontal portion with the horizontal portion extending at least partially into a sidewall spacer at a sidewall of the single diffusion break; forming a gate contact to a gate of the first transistor; forming a first via contacting the vertical portion of the L-shaped source/drain contact and a second via contacting the gate contact of the first transistor; and forming a metal track, the metal track having a first portion contacting the first via and a second portion contacting the second via.

In one embodiment, forming the L-shaped source/drain contact includes creating an opening to expose a source/drain region of the first transistor, a sidewall of the opening extending into the single diffusion break; filling the opening with a conductive material to form a conductive stud; and removing a portion of the conductive stud thereby forming the L-shaped source/drain contact having a vertical portion of the conductive stud on top of a horizontal portion of the conductive stud.

In another embodiment, creating the opening includes forming a dielectric layer covering the source/drain region and the gate of the first transistor and the single diffusion break; and etching through the dielectric layer and at least a portion of the single diffusion break to create the opening that exposes the source/drain region of the first transistor.

In yet another embodiment, the gate contact is directly on top of an active channel region of the first transistor.

According to one embodiment, the method further includes forming a source/drain contact to a source/drain region of the second transistor, the source/drain region of the second transistor being next to the single diffusion break.

According to another embodiment, the method further includes forming a source/drain contact to a source/drain region of a third transistor, the third transistor being stacked underneath the single diffusion break and the first and the second transistor, the source/drain contact to the source/drain region of the third transistor having an inverted L-shape with a vertical portion partially underneath a backside single diffusion break.

### BRIEF DESCRIPTION OF THE DRAWINGS

The present invention will be understood and appreciated more fully from the following detailed description of embodiments of present invention, taken in conjunction with accompanying drawings of which:

FIG. 1A to FIG. 17A are demonstrative illustrations of cross-sectional views and FIG. 1B to FIG. 17B are simplified top views of a semiconductor structure at various steps of manufacturing thereof according to embodiments of present invention; and

FIG. 18 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the case of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

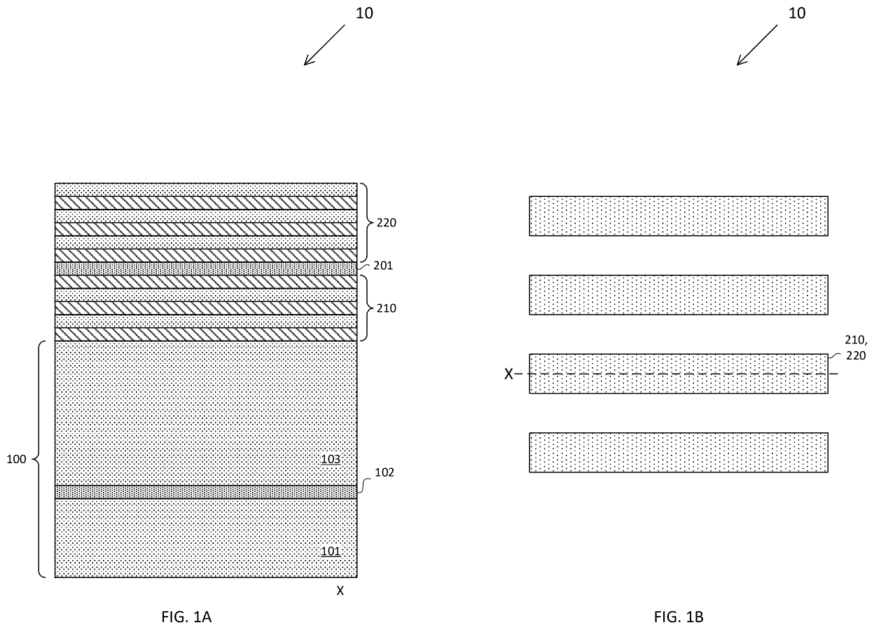

FIG. 1A is a demonstrative illustration of a cross-sectional view and FIG. 1B is a simplified top view of a semiconductor structure in a step of manufacturing thereof according to one embodiment of present invention. More specifically, FIG. 1A illustrates a cross-sectional view of the semiconductor structure with a cross-section made along a dashed line X as illustrated in FIG. 1B. In other words, the cross-section in FIG. 1A is made across the gate in a direction along the length of gate of the transistors. As its purpose is to show the location of cross-section illustrated in FIG. 1A, the simplified top view of FIG. 1B may selectively illustrate only key elements such as, for example, nanosheets and gates of the transistors that are formed, previously formed, yet to be formed, or whose views may sometimes be obstructed. Other elements such as dielectric cap layer, sidewall spacers, and details of source/drain regions may not necessarily be illustrated in order not to overcrowd the top view, and to the extent that their omission from FIG. 1B does not hinder the description of embodiments of present invention, which is mainly provided hereinafter with reference to the cross-sectional view of FIG. 1A.

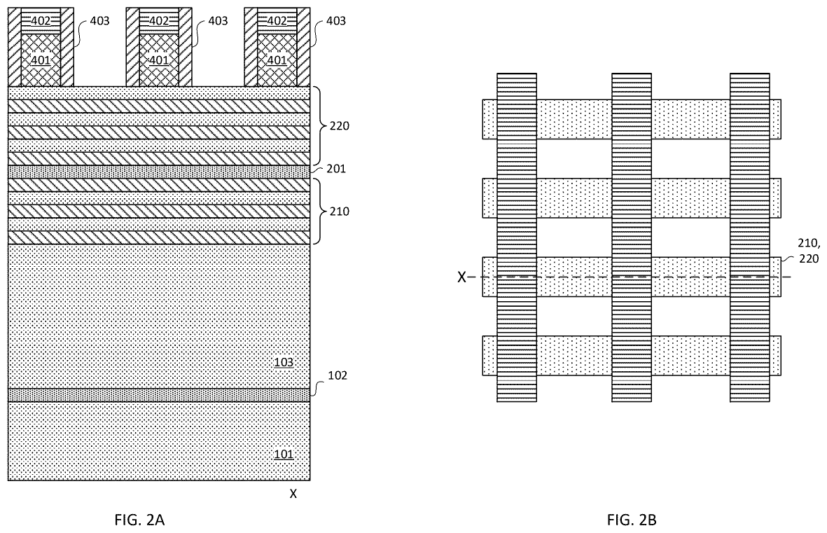

Likewise, FIG. 2A to FIG. 17A are demonstrative cross-sectional views and FIG. 2B to FIG. 17B are simplified top views of the semiconductor structure, at various manufacturing steps and/or for different embodiments, illustrated in manners similar to FIGS. 1A and 1B respectively.

Embodiments of present invention provide forming a semiconductor structure 10 by first receiving or providing a semiconductor substrate 100. The semiconductor substrate 100 may include a bulk silicon (Si) substrate 101, an etch-stop layer 102 on top of the Si substrate 101, and a Si layer 103 on top of the etch-stop layer 102. In one embodiment, the etch-stop layer 102 may be a layer of silicon-germanium (SiGe) containing a predetermined percentage of germanium (Ge) such as, for example, 25 at. % and a layer of such composition may be generally referred to as a SiGe25 layer. In other words, the etch-stop layer 102 may be a SiGe25 layer. In another embodiment, the semiconductor substrate 100 may be a silicon-on-insulator (SOI) substrate with an insulating layer of, for example, silicon-oxide (SiO₂) or silicon-nitride (SiN) between a bulk Si substrate 101 and a Si layer 103. This insulating layer may work or function as an etch-stop layer 102.

Embodiments of present invention further provide proceeding to form a first raw stack of nanosheets 210 on top of the semiconductor substrate 100; a sacrificial insulation sheet 201 on top of the first raw stack of nanosheets 210; and a second raw stack of nanosheets 220 on top of the sacrificial insulation sheet 201.

The first and the second raw stack of nanosheets 210 and 220 may be formed by first forming or depositing a first and a second stack of blanket semiconductor sheets such as, for example, a first and a second stack of alternating blanket Si sheets and sacrificial SiGe sheets on top of the semiconductor substrate 100. The first and the second stack of blanket semiconductor sheets may be vertically separated by a blanket sacrificial insulation sheet. This first and the second stack of blanket semiconductor sheets may then be patterned, for example, through a lithographic patterning and etch process to form the first raw stack of nanosheets 210 and the second raw stack of nanosheets 220. In the meantime, the blanket sacrificial insulation sheet may be patterned to form the sacrificial insulation sheet 201.

FIG. 2A is a demonstrative illustration of a cross-sectional view and FIG. 2B is a simplified top view of a semiconductor structure in a step of manufacturing thereof according to one embodiment of present invention. More particularly, following the step illustrated in FIGS. 1A and 1B, embodiments of present invention provide forming one or more dummy gates 401 on top of the first and the second raw stack of nanosheets 210 and 220. In doing so, a layer of dummy gate material such as, for example, polysilicon or dielectric may be deposited blanketly to cover the first and the second raw stack of nanosheets 210 and 220. The deposition process may be a chemical-vapor-deposition (CVD) process, a physical-vapor-deposition (PVD) process, an atomic-layer-deposition (ALD) process, or any other currently existing or future developed process. Next, a layer of hard mask material, such as a layer of SiN, may be formed on top of the layer of dummy gate material, which is then lithographically patterned to form a hard mask 402. The pattern of the hard mask 402 is then transferred, for example through a selective etch process, onto the layer of dummy gate material thereby forming the one or more dummy gates 401. The one or more dummy gates 401 may be patterned to have a direction or orientation that is perpendicular to the first and the second raw stack of nanosheets 210 and 220, as is demonstratively illustrated in FIG. 2B, representing a width direction of the gates to be formed.

After forming the one or more dummy gates 401, sidewall spacers 403 may be formed at sidewalls of the one or more dummy gates 401. For example, a conformal dielectric layer may first be formed, for example through a deposition process, to cover the one or more dummy gates 401 and cover the exposed portions of the first and the second raw stack of nanosheets 210 and 220. A directional etch process may then be applied to remove or etch away horizontal portions of the conformal dielectric layer, thereby leaving only vertical portions of the conformal dielectric layer at sidewalls of the one or more dummy gates 401, and the hard mask 402 on top thereof, to form the sidewall spacers 403.

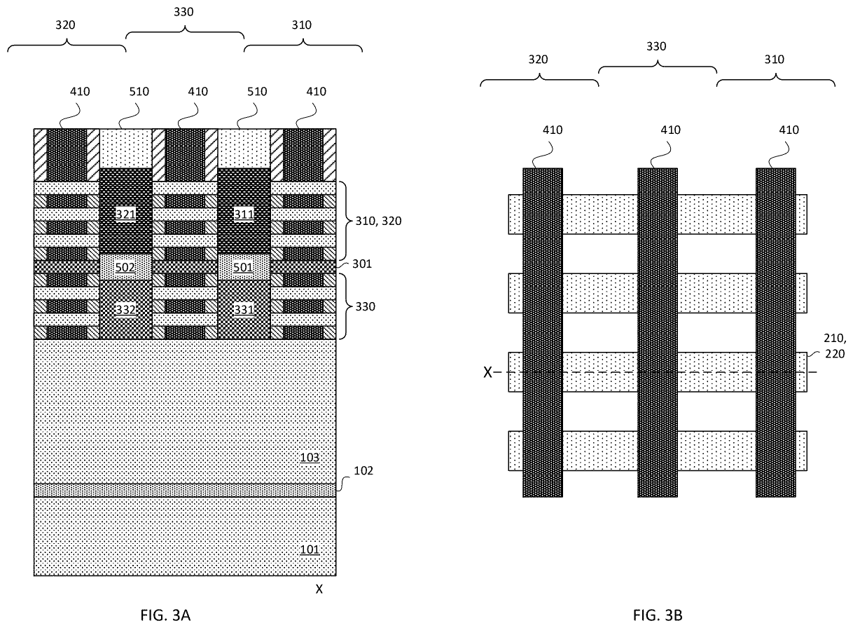

FIG. 3A is a demonstrative illustration of a cross-sectional view and FIG. 3B is a simplified top view of a semiconductor structure in a step of manufacturing thereof according to one embodiment of present invention. More particularly, following the step illustrated in FIGS. 2A and 2B, embodiments of present invention provide recessing the first and the second raw stack of nanosheets 210 and 220, using the one or more dummy gates 401 and sidewall spacers 403 as etch mask, to create a plurality of stacks of nanosheets for forming a plurality of nanosheet transistors. For example, multiple stacks of nanosheets may be created from the second raw stack of nanosheets 220 to form a first nanosheet transistor 310 and a second nanosheet transistor 320. Similarly, multiple stacks of nanosheets may be created from the first raw stack of nanosheets 210 to form, for example, a third nanosheet transistor 330.

The multiple stacks of nanosheets may each include a stack of alternating Si sheets and sacrificial SiGe sheets. As being described below in more details, the Si sheets may form active channel regions of their respective nanosheet transistors while the sacrificial SiGe sheets may be selectively removed later and replaced with a conductive material to form one or more metal gates, as being described below in more details. Next, inner spacers may be formed at end portions of the sacrificial SiGe sheets of the multiple stacks of nanosheets.

Embodiments of present invention also provide removing and replacing the sacrificial insulation sheet 201 with a self-aligned middle isolation (SAMI) layer 301, which may be a layer of dielectric material such as, SiO₂, SiN, silicon-carbon (SiC), silicon-boron-carbonitride (SiBCN), silicon-oxycarbide (SiOC), silicon-oxycarbonitride (SiOCN), or other suitable materials. The SAMI layer 301 may be formed after the process of forming the plurality of stacks of nanosheets to separate top transistors such as the first and the second nanosheet transistor 310 and 320 from bottom transistors such as the third nanosheet transistor 330.

Embodiments of present invention further provide forming source/drain (S/D) regions of the plurality of nanosheet transistors. For example, a first and a second S/D region 331 and 332 may be formed, through an epitaxial growth process from end surfaces of the Si sheets, for the third nanosheet transistor 330. Similarly, a first S/D region 311 may be formed for the first nanosheet transistor 310 and a first S/D region 321 may be formed for the second nanosheet transistor 320, through their respective epitaxial growth processes.

Embodiments of present invention further provide forming middle-dielectric-insulator (MDI) layers 501 and 502 on top of the first and the second S/D region 331 and 332 of the third nanosheet transistor 330. The MDI layers 501 and 502 may be SiO₂, SiN, SiC, SiBCN, SiOC, or SiOCN and may be formed in an area adjacent to the SAMI layer 301 which may have a same or different dielectric material. The MDI layers 501 and 502 may be formed, for example, by depositing a dielectric material layer on top of the first and the second S/D region 331 and 332, which is then first planarized and subsequently recessed in height to form the MDI layers 501 and 502. The MDI layers 501 and 502 are formed to insulate S/D regions of the top transistors, such as the first and the second nanosheet transistor 310 and 320, from S/D regions of the bottom transistors, such as the third nanosheet transistor 330.

In one embodiment, dielectric material may be deposited to form a dielectric layer 510 filling spaces between the one or more dummy gates 401 to cover the first S/D region 311 of the first nanosheet transistor 310 and the first S/D region 321 of the second nanosheet transistor 320. A chemical-mechanical-polishing (CMP) process may be applied to planarize a top surface of the dielectric layer 510 and remove the hard masks 402 until the one or more dummy gates 401 underneath the hard masks 402 are revealed or exposed for further processing.

After being revealed, the one or more dummy gates 401 and the sacrificial SiGe sheets between the Si sheets may be selectively removed, in a replacement-metal-gate (RMG) process, and replaced with one or more metal gates 410, thereby forming the first and the second nanosheet transistor 310 and 320. Similarly, and through the same or a different RMG process, a metal gate 410 may be formed, between the first and the second S/D region 331 and 332, for the third nanosheet transistor 330.

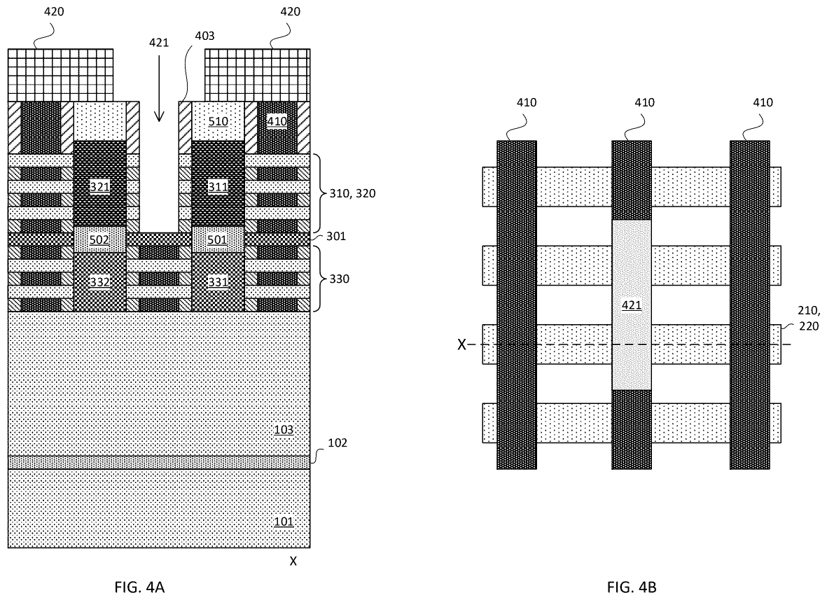

FIG. 4A is a demonstrative illustration of a cross-sectional view and FIG. 4B is a simplified top view of a semiconductor structure in a step of manufacturing thereof according to one embodiment of present invention. More particularly, following the step illustrated in FIGS. 3A and 3B, embodiments of present invention provide forming a hard mask 420 covering the metal gate 410 of the first nanosheet transistor 310 and the metal gate 410 of the second nanosheet transistor 320. The hard mask 420 may expose only the metal gate 410, and the surrounding sidewall spacers, between the first S/D region 311 and the first S/D region 321 where a single diffusion break (SDB) is to be formed for insulating or isolating the first nanosheet transistor 310 from the second nanosheet transistor 320. Next, the exposed metal gate 410 may be selectively removed, together with subsequently exposed Si sheets of the stack of nanosheets, thereby creating an opening 421. The opening 421 exposes the SAMI layer 301 above the metal gate of the third nanosheet transistor 330.

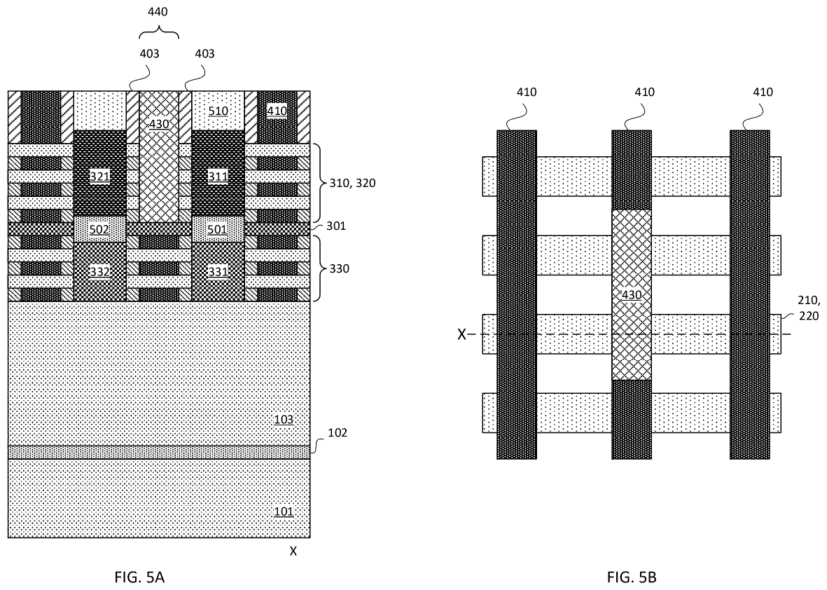

FIG. 5A is a demonstrative illustration of a cross-sectional view and FIG. 5B is a simplified top view of a semiconductor structure in a step of manufacturing thereof according to one embodiment of present invention. More particularly, following the step illustrated in FIGS. 4A and 4B, embodiments of present invention provide filling the opening 421 with a dielectric material, such as SiO₂, SiN, SiC, SiBCN, SiOC, SiOCN, to form a dielectric layer 430 between the first S/D region 311 of the first nanosheet transistor 310 and the first S/D region 321 of the second nanosheet transistor 320. In one embodiment, a CMP process may be applied to planarize a top surface of the dielectric layer 430 such that it becomes coplanar with the top surface of the metal gate 410, thereby forming a single diffusion break (SDB) 440. The first and the second nanosheet transistors 310 and 320 are adjacent to the SDB 440, via the sidewall spacers 403 and one or more inner spacers, and isolated or insulated from each other by the SDB 440.

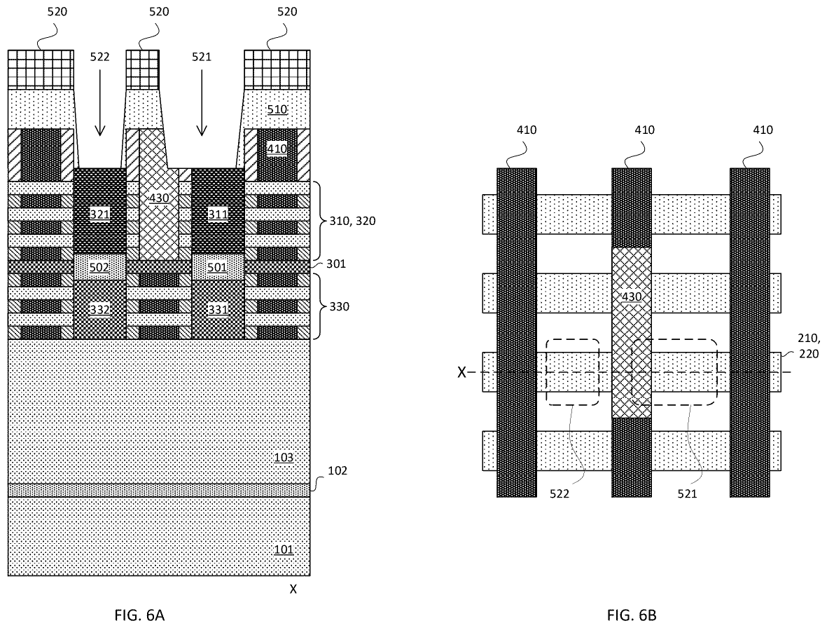

FIG. 6A is a demonstrative illustration of a cross-sectional view and FIG. 6B is a simplified top view of a semiconductor structure in a step of manufacturing thereof according to one embodiment of present invention. More particularly, following the step illustrated in FIGS. 5A and 5B, embodiments of present invention provide depositing additional dielectric material on top of, thereby expanding, the dielectric layer 510. The dielectric layer 510 may cover the SDB 440 and the metal gates 410. Next, a hard mask 520 may be formed on top of the dielectric layer 510 through a lithographic patterning and etch process. A selective and/or directional etch process may be applied to transfer one or more openings in the hard mask 520 onto the dielectric layer 510 to create openings for forming one or more S/D contacts. For example, a first opening 521 may be created that etches into the dielectric layer 510 on top of the first S/D region 311 of the first nanosheet transistor 310. The first opening 521 may be made sufficient wide such that a sidewall of the first opening 521 may be, in one embodiment, made into the SDB 440. The first opening 521 may expose a top surface of the first S/D region 311 of the first nanosheet transistor 310 and a portion of the SDB 440. Also, for example, a second opening 522 may be made to expose a top surface of the first S/D region 321 of the second nanosheet transistor 320. Unlike the first opening 521, the second opening 522 may be substantially aligned with the first S/D region 321 of the second nanosheet transistor 320.

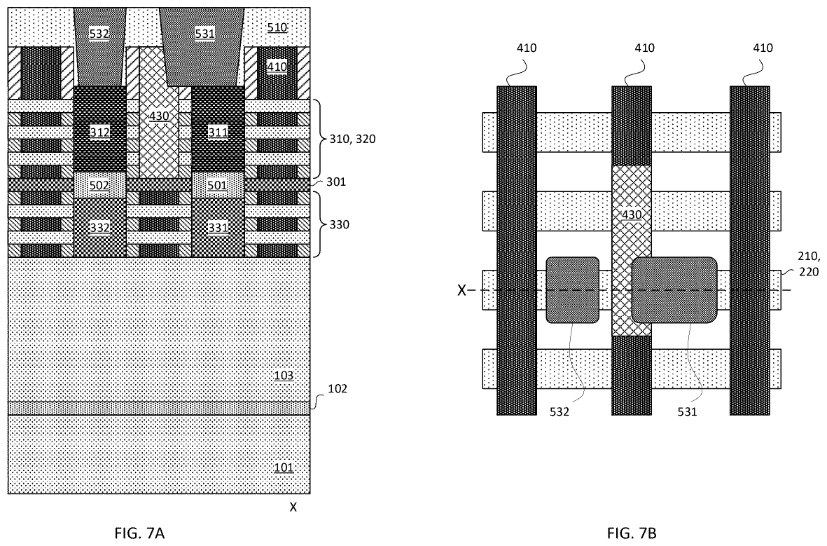

FIG. 7A is a demonstrative illustration of a cross-sectional view and FIG. 7B is a simplified top view of a semiconductor structure in a step of manufacturing thereof according to one embodiment of present invention. More particularly, following the step illustrated in FIGS. 6A and 6B, embodiments of present invention provide filling the first and the second opening 521 and 522 with a conductive material such as, for example, tungsten (W), copper (Cu), ruthenium (Ru), aluminum (Al), or other suitable conductive material through a deposition process such as, for example, a CVD process, a PVD process, or an ALD process. Filling the first opening 521 creates a conductive stud 531, which may later be processed to form a first S/D contact. Following the shape of the first opening 521, the conductive stud 531 may, in one embodiment, be made partially into the sidewall spacer 403 at the sidewall of the SDB 440 and may, in another embodiment, be made through the sidewall spacer 403 and partially into the SDB 440. In the meantime, filling the second opening 522 creates a second S/D contact 532. The second S/D contact 532 may be made between the two sidewall spacers 403 surrounding the first S/D region 312 of the second nanosheet transistor 320, and thus substantially aligned with the first S/D region 312.

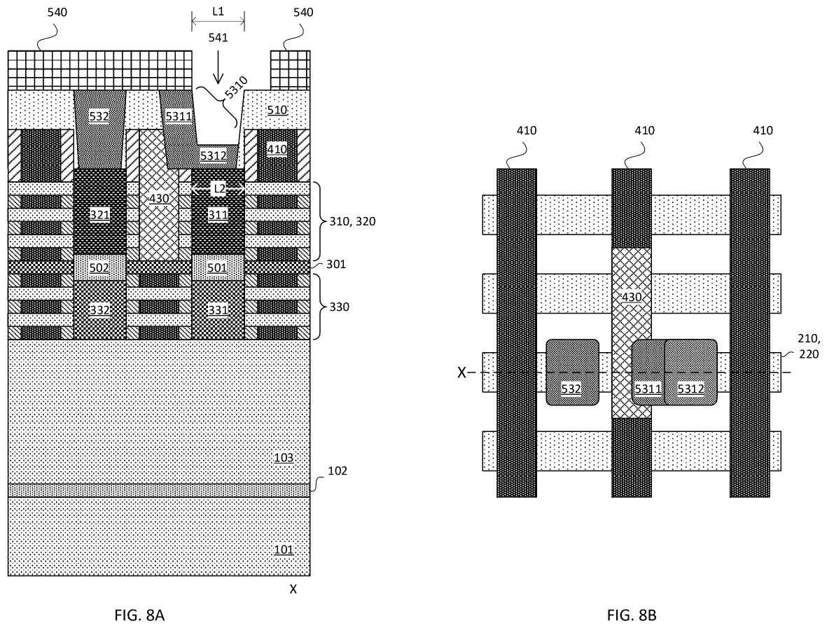

FIG. 8A is a demonstrative illustration of a cross-sectional view and FIG. 8B is a simplified top view of a semiconductor structure in a step of manufacturing thereof according to one embodiment of present invention. More particularly, following the step illustrated in FIGS. 7A and 7B, embodiments of present invention provide forming a hard mask 540 on top of the dielectric layer 510 and on top of the conductive stud 531 and the second S/D contact 532. The hard mask 540 may include an opening that overlaps with a portion of the conductive stud 531 and may optionally overlap with a portion of the dielectric layer 510 next to the exposed portion of the conductive stud 531. The portion of conductive stud 531 exposed by the opening may be a portion that is closer to the metal gate 410 of the first nanosheet transistor 310, than rest of the conductive stud 531.

Embodiments of present invention provide removing a top portion of this exposed portion of conductive stud 531 to create an opening 541 through a selective etch process. The selective etch process may etch the conductive material of the conductive stud 531 but leave the dielectric layer 510, even though exposed, substantially unetched. The opening 541 so created may therefore be self-aligned to the dielectric layer 510 including any remaining portion of the dielectric layer 510 directly above the first S/D region 311 of the first nanosheet transistor 310.

The selective etch process of the conductive stud 531 may thus create an L-shaped first S/D contact 5310 that includes a vertical portion of the conductive stud 531 forming a vertical portion 5311 and a horizontal portion of the conductive stud 531 forming a horizontal portion 5312, with the vertical portion 5311 on top of the horizontal portion 5312. The vertical portion 5311 of the L-shaped first S/D contact 5310 may in one embodiment be partially embedded in the sidewall spacer 403 at the sidewall of the SDB 440, and in another embodiment be partially embedded in the SDB 440. The horizontal portion 5312 of the L-shaped first S/D contact 5310 may extend from a top surface of the first S/D region 311 into the sidewall spacer 403, and in some embodiments extends into the SDB 440.

In one embodiment, the opening 541 surrounded by the L-shaped first S/D contact 5310 and the dielectric layer 510 may have a horizonal width L1, at the top of the opening 541, that is substantially equal to or larger than two-third (2/) of a length L2 of the first S/D region 311 of the first nanosheet transistor 310. In another embodiment, a portion of the horizontal portion 5312 that is not covered by the vertical portion 5311 may be substantially equal to or larger than two-third (⅔) of the length L2 of the first S/D region 311 of the first nanosheet transistor 310.

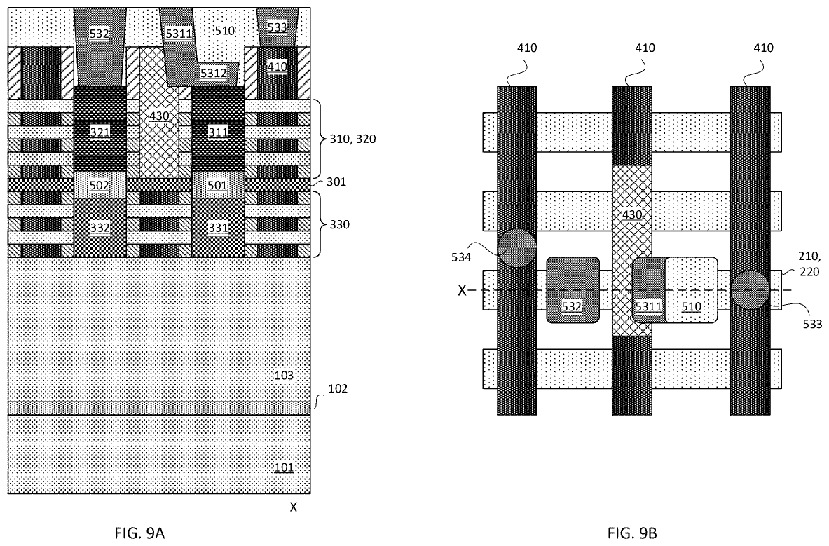

FIG. 9A is a demonstrative illustration of a cross-sectional view and FIG. 9B is a simplified top view of a semiconductor structure in a step of manufacturing thereof according to one embodiment of present invention. More particularly, following the step illustrated in FIGS. 8A and 8B, embodiments of present invention provide filling the opening 541 with additional dielectric material to form or restore the dielectric layer 510. The dielectric layer 510 may cover a sidewall of the vertical portion 5311 of the L-shaped first S/D contact 5310 and on top of the portion of the horizontal portion 5312 of the L-shaped first S/D contact 5310 that is not covered by the vertical portion 5311 of the L-shaped first S/D contact 5310.

Embodiments of present invention may further provide forming a gate contact 533 through the dielectric layer 510 to contact the metal gate 410 of the first nanosheet transistor 310. In one embodiment, the gate contact 533 and the vertical portion 5311 of the L-shaped first S/D contact 5310 may be separated by a distance that is substantially equal to or larger than two-third (⅔) of the length L2 of the first S/D region 311 of the first nanosheet transistor 310. Next, a CMP process may be applied to planarize, and make coplanar, top surfaces of the dielectric layer 510, the L-shaped first S/D contact 5310, the second S/D contact 532, and the gate contact 533.

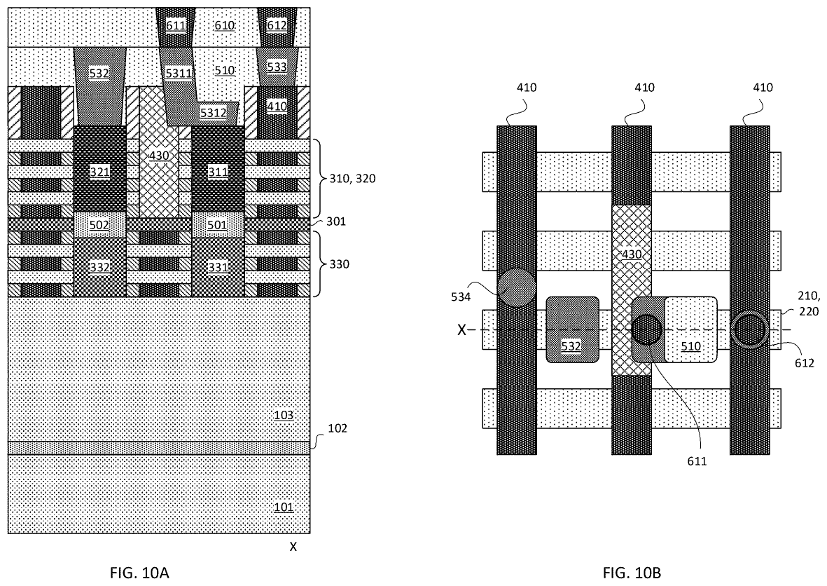

FIG. 10A is a demonstrative illustration of a cross-sectional view and FIG. 10B is a simplified top view of a semiconductor structure in a step of manufacturing thereof according to one embodiment of present invention. More particularly, following the step illustrated in FIGS. 9A and 9B, embodiments of present invention provide forming a dielectric layer 610, for example through a CVD process, a PVD process, or an ALD process, to cover the top surfaces of the dielectric layer 510, the L-shaped first S/D contact 5310, the second S/D contact 532, and the gate contact 533. Contact vias such as a first contact via 611 and a second contact via 612 may be formed inside and through the dielectric layer 610, and the first and the second contact vias 611 and 612 may contact, respectively, the vertical portion 5311 of the L-shaped first S/D contact 5310 and the gate contact 533.

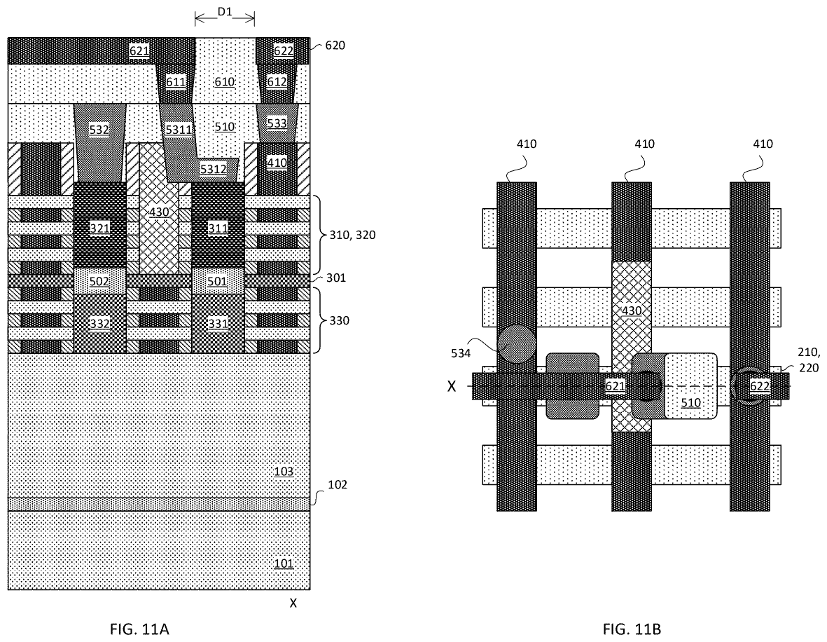

FIG. 11A is a demonstrative illustration of a cross-sectional view and FIG. 11B is a simplified top view of a semiconductor structure in a step of manufacturing thereof according to one embodiment of present invention. More particularly, following the step illustrated in FIGS. 10A and 10B, embodiments of present invention provide expanding the dielectric layer 610, upwardly by adding additional dielectric material on the top, to cover the first and the second contact vias 611 and 612, and subsequently forming a metal line 620 of a metal track in the expanded dielectric layer 610. The metal line 620 may include a first portion 621 that is formed to be in contact with the first contact via 611 and a second portion 622 that is formed to be in contact with the second contact via 612. The first and the second portion 621 and 622 of the metal line 620 may be formed in a same metal track, therefore are longitudinally aligned. The first and the second portion 621 and 622 may be separated by a gap DI with a width that is at least two-third (⅔) of the length L2 of the first S/D region 311 of the first nanosheet transistor 310. This relatively large gap DI between the first and the second portion 621 and 622 of the metal line 620 enables both the L-shaped first S/D contact 5310 and the gate contact 533 to contact their respective portions of a same metal line, that is the first portion 621 and the second portion 622 of the metal line 620, without the fear of causing short, where the first and the second portion of the metal line are formed in a same metal track.

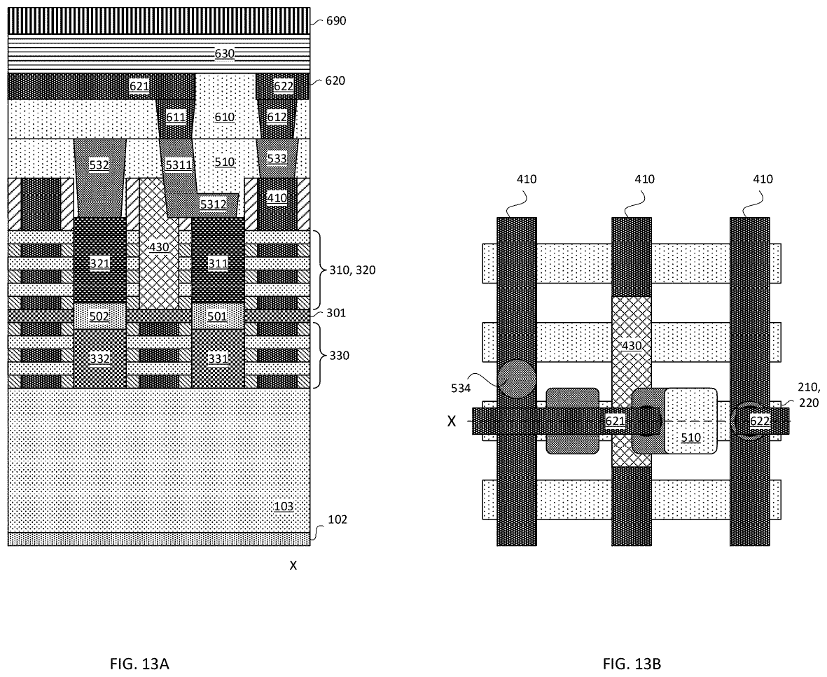

L-shaped S/D contacts, such as the L-shaped first S/D contact 5310, may be used not only for the top transistors, such as the first and the second nanosheet transistor 310 and 320 formed at the frontside of a semiconductor device or chip, but also for the bottom transistors, such as the third nanosheet transistor 330 formed at the backside of the semiconductor device or chip. Details of forming L-shaped S/D contact for a bottom transistor are provided below starting at FIGS. 13A and 13B.

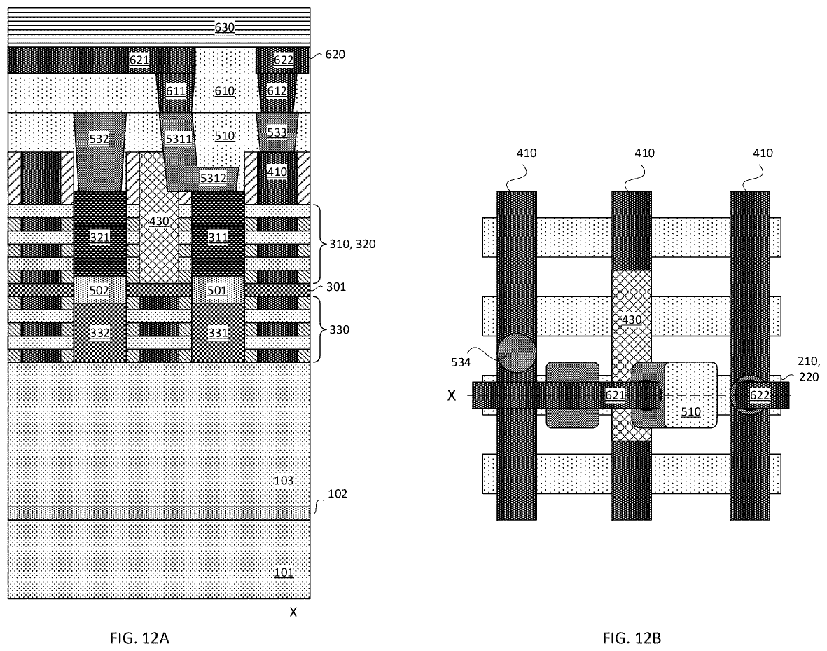

FIG. 12A is a demonstrative illustration of a cross-sectional view and FIG. 12B is a simplified top view of a semiconductor structure in a step of manufacturing thereof according to one embodiment of present invention. More particularly, following the step illustrated in FIGS. 11A and 11B, embodiments of present invention provide forming a back-end-of-line (BEOL) structure 630 on top of the dielectric layer 610 and the metal line 620. The BEOL structure 630 provides power and/or signal routing functions to the plurality of nanosheet transistors formed in and above the semiconductor substrate 100.

FIG. 13A is a demonstrative illustration of a cross-sectional view and FIG. 13B is a simplified top view of a semiconductor structure in a step of manufacturing thereof according to one embodiment of present invention. More particularly, after forming structures at the frontside of the semiconductor structure 10, embodiments of present invention provide attaching a handling wafer 690 onto the BEOL structure 630; and flipping the semiconductor structure 10 upside-down to process from the backside of the semiconductor structure 10. For example, the bulk Si substrate 101 may be selectively removed through, for example, a CMP process, a wet etch process, a grinding process, or a combination thereof or other suitable processes. The removal of the bulk Si substrate 101 stops at the etch-stop layer 102 for better process control.

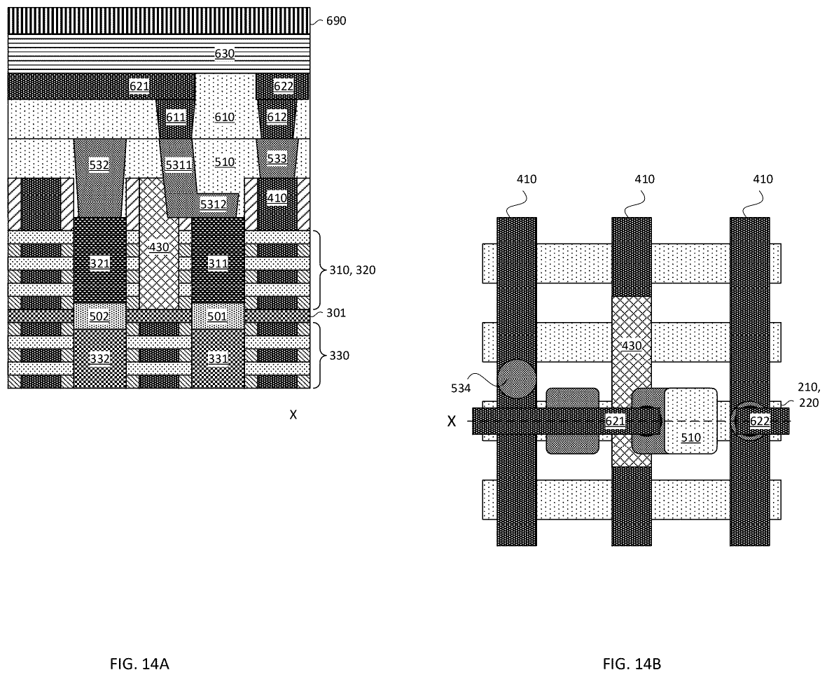

FIG. 14A is a demonstrative illustration of a cross-sectional view and FIG. 14B is a simplified top view of a semiconductor structure in a step of manufacturing thereof according to one embodiment of present invention. More particularly, following the step illustrated in FIGS. 13A and 13B, embodiments of present invention provide continuing to selectively remove the etch-stop layer 102 and the Si layer 103 exposed by the removal of the etch-stop layer 102. The removal of the Si layer 103 exposes a bottom surface of the first and the second S/D regions 331 and 332 of the third nanosheet transistor 330 underneath the SDB 440, and underneath the first and the second nanosheet transistor 310 and 320.

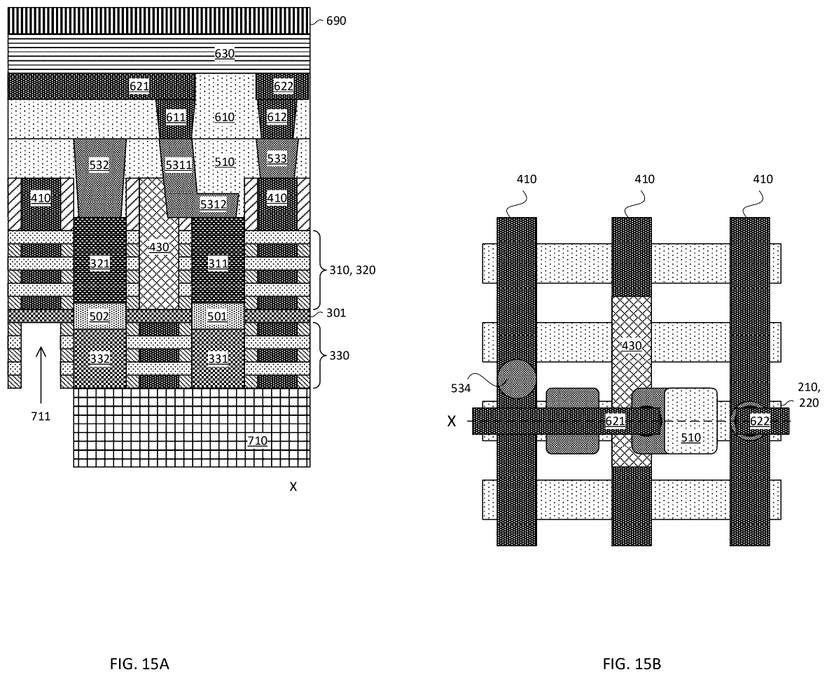

FIG. 15A is a demonstrative illustration of a cross-sectional view and FIG. 15B is a simplified top view of a semiconductor structure in a step of manufacturing thereof according to one embodiment of present invention. More particularly, following the step illustrated in FIGS. 14A and 14B, embodiments of present invention provide forming a hard mask 710, from the backside of the semiconductor structure 10, covering the third nanosheet transistor 330. The hard mask 710 may include an opening that exposes a metal gate 410 adjacent to the second S/D region 332 of the third nanosheet transistor 330. The metal gate 410, together with the Si sheets surrounded by the metal gate 410, may subsequently be removed through a selective etch process, thereby creating an opening 711 for forming a backside single diffusion break.

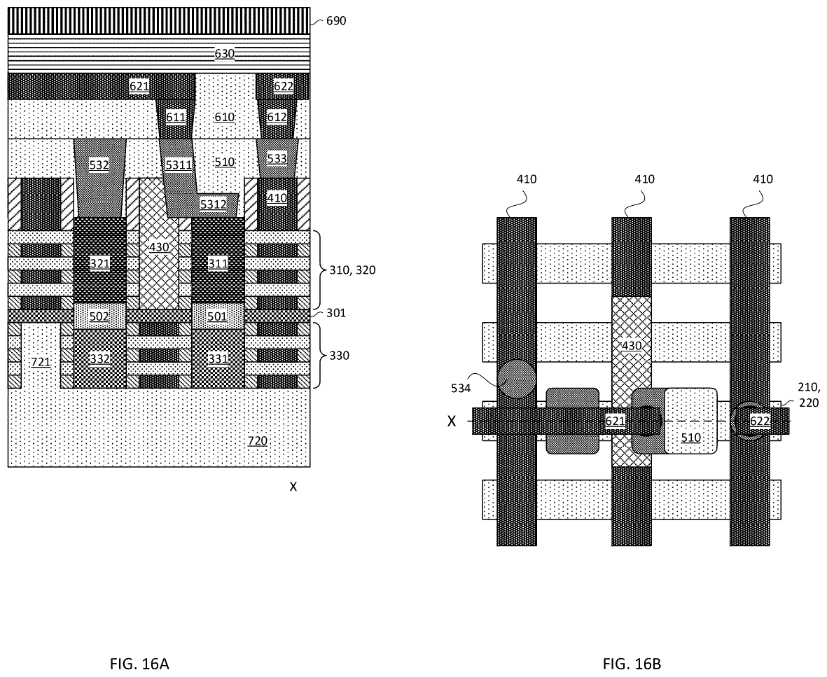

FIG. 16A is a demonstrative illustration of a cross-sectional view and FIG. 16B is a simplified top view of a semiconductor structure in a step of manufacturing thereof according to one embodiment of present invention. More particularly, following the step illustrated in FIGS. 15A and 15B, embodiments of present invention provide filling the opening with a dielectric material to form a backside single diffusion break (BSDB) 721. Dielectric material of the BSDB 721 may include, for example, SiO₂, SiN, SiC, SiBCN, SiOC, SiOCN, or other suitable insulating materials. The BSDB 721 provides isolation and/or insulation of the third nanosheet transistor 330 from other neighboring active devices such as, for example, another nanosheet transistor.

After forming the BSDB 721, embodiments of present invention provide forming a backside interlevel-dielectric (BILD) layer 720 covering the third nanosheet transistor 330, the BSDB 721, and any surrounding semiconductor structures.

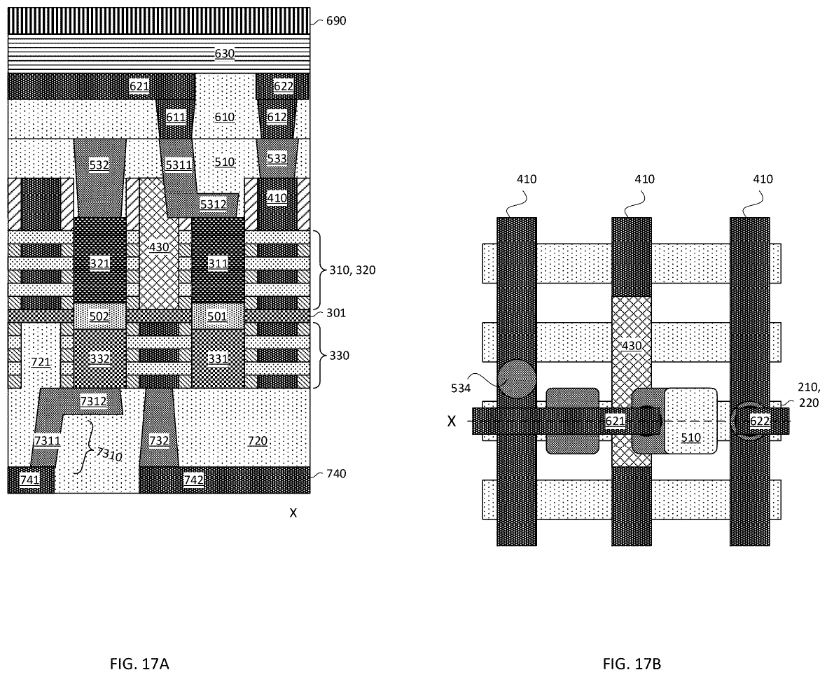

FIG. 17A is a demonstrative illustration of a cross-sectional view and FIG. 17B is a simplified top view of a semiconductor structure in a step of manufacturing thereof according to one embodiment of present invention. More particularly, following the step illustrated in FIGS. 16A and 16B, embodiments of present invention provide forming a gate contact 732 and an L-shaped S/D contact 7310 that has a vertical portion 7311 and a horizontal portion 7312. The horizontal portion 7312 of the L-shaped S/D contact 7310 is in contact with the second S/D region 332 of the third nanosheet transistor 330; and extends horizontally into a region directly underneath the BSDB 721. In the meantime, the vertical portion 7311 of the L-shaped S/D contact 7310 is at least partially underneath the BSDB 721.

After forming the L-shaped S/D contact 7310 and the gate contact 732, embodiments of present invention provide forming a backside metal line 740. The backside metal line 740 has a first portion 741 and a second portion 742 formed along a same metal track. In other words, the first portion 741 and the second portion 742 of the backside metal line 740 are longitudinally aligned. The first portion 741 is formed to be in contact with the vertical portion 7311 of the L-shaped S/D contact 7310 and the second portion 742 is formed to be in contact with the gate contact 732. The expanded distance between the vertical portion 7311 of the L-shaped S/D contact 7310 and the gate contact 732 helps mitigate the risk of short between the first and the second portion 741 and 742 of the backside metal line 740.

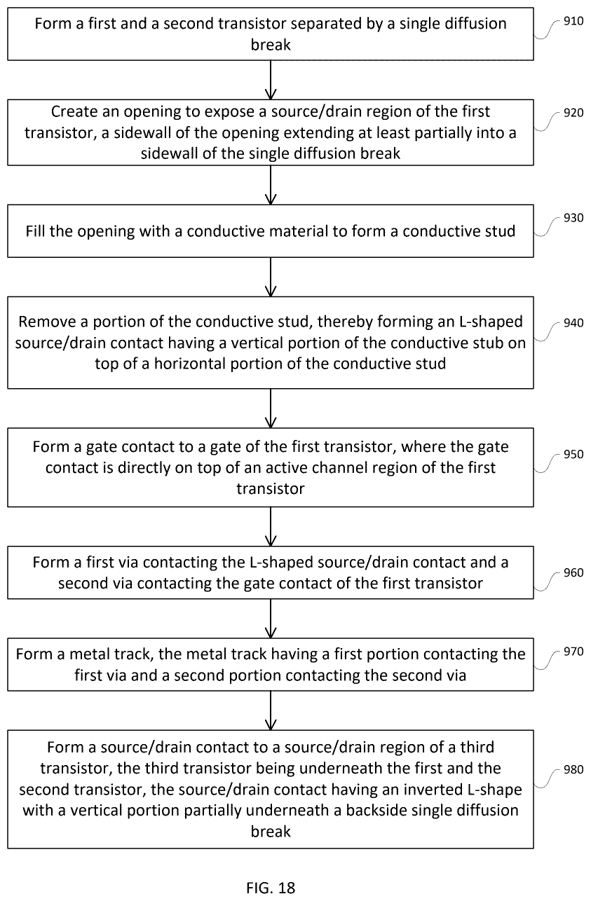

FIG. 18 is a demonstrative illustration of a flow-chart of a method of manufacturing a semiconductor structure according to embodiments of present invention. The method includes (910) forming a first and a second transistor separated by a single diffusion break; (920) creating an opening to expose a source/drain region of the first transistor, a sidewall of the opening extending at least partially into a sidewall of the single diffusion break; (930) filling the opening with a conductive material to form a conductive stud; (940) removing a portion of the conductive stub, thereby forming an L-shaped source/drain contact having a vertical portion of the conductive stud on top of a horizontal portion of the conductive stud; (950) forming a gate contact to a gate of the first transistor, where the gate contact is directly on top of an active channel region of the first transistor; (960) forming a first via contacting the L-shaped source/drain contact and a second via contacting the gate contact of the first transistor; (970) forming a first via contacting the L-shaped source/drain contact and a second via contacting the gate contact of the first transistor; and (980) form a source/drain contact to a source/drain region of a third transistor, the third transistor being underneath the first and the second transistor, the source/drain contact having an inverted L-shape with a vertical portion partially underneath a backside single diffusion break.

Various examples may possibly be described by one or more of the following features in the following numbered clauses:

Clause 1: A semiconductor structure comprising a first and a second transistor separated by a single diffusion break; and a source/drain contact to a source/drain region of the first transistor, the source/drain region being next to the single diffusion break, wherein the source/drain contact has an L-shape having a vertical portion on top of a horizontal portion, the horizontal portion extending at least partially into a sidewall spacer at a sidewall of the single diffusion break.

Clause 2: The semiconductor structure of clause 1, wherein the horizontal portion of the source/drain contact extends into the single diffusion break and the vertical portion of the source/drain contact is partially embedded in the single diffusion break.

Clause 3: The semiconductor structure of clause 1, further comprising a gate contact to a gate of the first transistor, the gate contact being directly above an active channel region of the first transistor.

Clause 4: The semiconductor structure of clause 3, further comprising a metal track having a first portion and a second portion separated by a dielectric layer, a first via, and a second via; wherein the first via connects the source/drain contact to the first portion of the metal track and the second via connects the gate contact to the second portion of the metal track.

Clause 5: The semiconductor structure of clause 4, wherein a gap between the first and the second portion of the metal track is equal to or larger than two-third (⅔) of a length of the source/drain region of the first transistor.

Clause 6: The semiconductor structure of clause 1, further comprising a third transistor underneath the first and the second transistor and the single diffusion break (SDB), the third transistor having a source/drain region next to a backside single diffusion break (BSDB) and a gate directly underneath the SDB, and a source/drain contact to the source/drain region of the third transistor that extends into the BSDB.

Clause 7: The semiconductor structure of clause 6, further comprising a backside metal track, wherein the source/drain contact to the source/drain region of the third transistor connects to a first portion of the backside metal track, and a gate contact to the gate underneath the SDB connects to a second portion of the backside metal track.

Clause 8: The semiconductor structure of clause 6, wherein the source/drain contact to the source/drain region of the third transistor has an inverted L-shape with a vertical portion at least partially underneath the BSDB.

Clause 9: A method of forming a semiconductor structure comprising forming a first and a second transistor separated by a single diffusion break; forming an L-shaped source/drain contact of the first transistor, the L-shaped source/drain contact having a vertical portion on top of a horizontal portion with the horizontal portion extending at least partially into a sidewall spacer at a sidewall of the single diffusion break; forming a gate contact to a gate of the first transistor; forming a first via contacting the vertical portion of the L-shaped source/drain contact and a second via contacting the gate contact of the first transistor; and forming a metal track, the metal track having a first portion contacting the first via and a second portion contacting the second via.

Clause 10: The method of clause 9, wherein forming the L-shaped source/drain contact comprises creating an opening to expose a source/drain region of the first transistor, a sidewall of the opening extending into the single diffusion break; filling the opening with a conductive material to form a conductive stud; and removing a portion of the conductive stud thereby forming the L-shaped source/drain contact having a vertical portion of the conductive stud on top of a horizontal portion of the conductive stud.

Clause 11: The method of clause 10, wherein creating the opening comprises forming a dielectric layer covering the source/drain region and the gate of the first transistor and the single diffusion break; and etching through the dielectric layer and at least a portion of the single diffusion break to create the opening that exposes the source/drain region of the first transistor.

Clause 12: The method of clause 9, wherein the gate contact is directly on top of an active channel region of the first transistor.

Clause 13: The method of clause 9, further comprising forming a source/drain contact to a source/drain region of the second transistor, the source/drain region of the second transistor being next to the single diffusion break.

Clause 14: The method of clause 9, further comprising forming a source/drain contact to a source/drain region of a third transistor, the third transistor being stacked underneath the single diffusion break and the first and the second transistor, the source/drain contact to the source/drain region of the third transistor having an inverted L-shape with a vertical portion partially underneath a backside single diffusion break.

Clause 15: A semiconductor structure comprising a first and a second transistor separated by a single diffusion break; and a source/drain contact to a source/drain region of the first transistor, the source/drain region being next to the single diffusion break, wherein the source/drain contact has an L-shape having a vertical portion on top of a horizontal portion, the vertical portion being partially embedded in the single diffusion break.

Clause 16: The semiconductor structure of clause 15, further comprising a gate contact to a gate of the first transistor, the gate contact being directly above an active channel region of the first transistor.

Clause 17: The semiconductor structure of clause 16, further comprising a metal track having a first portion and a second portion that are separated by a gap, wherein the first portion of the metal track is connected to the vertical portion of the L-shaped source/drain contact of the first transistor and the second portion of the metal track is connected to the gate contact of the first transistor.

Clause 18: The semiconductor structure of clause 17, wherein the gap between the first and the second portion of the metal track is equal to or larger than two-third (⅔) of a length of the source/drain region of the first transistor.

Clause 19: The semiconductor structure of clause 15, further comprising a third transistor stacked underneath the single diffusion break and the first and the second transistor; wherein the third transistor has a source/drain region next to a backside single diffusion break; and a source/drain contact to the source/drain region of the third transistor has an inverted L-shape that extends into the backside single diffusion break.

Clause 20: The semiconductor structure of clause 19, further comprising a backside metal track having a first portion and a second portion, wherein the source/drain contact to the source/drain region of the third transistor connects to the first portion of the backside metal track, and a gate contact to a gate of the third transistor connects to the second portion of the backside metal track.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first and a second transistor separated by a single diffusion break; and
a source/drain contact to a source/drain region of the first transistor, the source/drain region being next to the single diffusion break,
wherein the source/drain contact has an L-shape having a vertical portion on top of a horizontal portion, the horizontal portion extending at least partially into a sidewall spacer at a sidewall of the single diffusion break.

2. The semiconductor structure of claim 1, wherein the horizontal portion of the source/drain contact extends into the single diffusion break and the vertical portion of the source/drain contact is partially embedded in the single diffusion break.

3. The semiconductor structure of claim 1, further comprising a gate contact to a gate of the first transistor, the gate contact being directly above an active channel region of the first transistor.

4. The semiconductor structure of claim 3, further comprising a metal track having a first portion and a second portion separated by a dielectric layer, a first via, and a second via; wherein the first via connects the source/drain contact to the first portion of the metal track and the second via connects the gate contact to the second portion of the metal track.

5. The semiconductor structure of claim 4, wherein a gap between the first and the second portion of the metal track is equal to or larger than two-third (⅔) of a length of the source/drain region of the first transistor.

6. The semiconductor structure of claim 1, further comprising a third transistor underneath the first and the second transistor and the single diffusion break (SDB), the third transistor having a source/drain region next to a backside single diffusion break (BSDB) and a gate directly underneath the SDB, and a source/drain contact to the source/drain region of the third transistor that extends into the BSDB.

7. The semiconductor structure of claim 6, further comprising a backside metal track, wherein the source/drain contact to the source/drain region of the third transistor connects to a first portion of the backside metal track, and a gate contact to the gate underneath the SDB connects to a second portion of the backside metal track.

8. The semiconductor structure of claim 6, wherein the source/drain contact to the source/drain region of the third transistor has an inverted L-shape with a vertical portion at least partially underneath the BSDB.

9. A method of forming a semiconductor structure comprising:
forming a first and a second transistor separated by a single diffusion break;
forming an L-shaped source/drain contact of the first transistor, the L-shaped source/drain contact having a vertical portion on top of a horizontal portion with the horizontal portion extending at least partially into a sidewall spacer at a sidewall of the single diffusion break;
forming a gate contact to a gate of the first transistor;
forming a first via contacting the vertical portion of the L-shaped source/drain contact and a second via contacting the gate contact of the first transistor; and
forming a metal track, the metal track having a first portion contacting the first via and a second portion contacting the second via.

10. The method of claim 9, wherein forming the L-shaped source/drain contact comprises:
creating an opening to expose a source/drain region of the first transistor, a sidewall of the opening extending into the single diffusion break;
filling the opening with a conductive material to form a conductive stud; and
removing a portion of the conductive stud thereby forming the L-shaped source/drain contact having a vertical portion of the conductive stud on top of a horizontal portion of the conductive stud.

11. The method of claim 10, wherein creating the opening comprises:
forming a dielectric layer covering the source/drain region and the gate of the first transistor and the single diffusion break; and
etching through the dielectric layer and at least a portion of the single diffusion break to create the opening that exposes the source/drain region of the first transistor.

12. The method of claim 9, wherein the gate contact is directly on top of an active channel region of the first transistor.

13. The method of claim 9, further comprising forming a source/drain contact to a source/drain region of the second transistor, the source/drain region of the second transistor being next to the single diffusion break.

14. The method of claim 9, further comprising forming a source/drain contact to a source/drain region of a third transistor, the third transistor being stacked underneath the single diffusion break and the first and the second transistor, the source/drain contact to the source/drain region of the third transistor having an inverted L-shape with a vertical portion partially underneath a backside single diffusion break.

15. A semiconductor structure comprising:
a first and a second transistor separated by a single diffusion break; and
a source/drain contact to a source/drain region of the first transistor, the source/drain region being next to the single diffusion break,
wherein the source/drain contact has an L-shape having a vertical portion on top of a horizontal portion, the vertical portion being partially embedded in the single diffusion break.

16. The semiconductor structure of claim 15, further comprising a gate contact to a gate of the first transistor, the gate contact being directly above an active channel region of the first transistor.

17. The semiconductor structure of claim 16, further comprising a metal track having a first portion and a second portion that are separated by a gap, wherein the first portion of the metal track is connected to the vertical portion of the L-shaped source/drain contact of the first transistor and the second portion of the metal track is connected to the gate contact of the first transistor.

18. The semiconductor structure of claim 17, wherein the gap between the first and the second portion of the metal track is equal to or larger than two-third (⅔) of a length of the source/drain region of the first transistor.

19. The semiconductor structure of claim 15, further comprising a third transistor stacked underneath the single diffusion break and the first and the second transistor; wherein the third transistor has a source/drain region next to a backside single diffusion break; and a source/drain contact to the source/drain region of the third transistor has an inverted L-shape that extends into the backside single diffusion break.

20. The semiconductor structure of claim 19, further comprising a backside metal track having a first portion and a second portion, wherein the source/drain contact to the source/drain region of the third transistor connects to the first portion of the backside metal track, and a gate contact to a gate of the third transistor connects to the second portion of the backside metal track.
